(19) United States
(12) Patent Application Publication
(10) Pub. No.: US 2012/0235342 A1
(43) Pub. Date: Sep. 20, 2012

(54) SUBSTRATE SUPPORT JIG

(75) Inventor: Noboru Kurata, Matsumoto-city (JP)

(73) Assignee: FUJI ELECTRIC CO., LTD., Kawasaki-Shi (JP)

(21) Appl. No.: 13/371,902

(22) Filed: Feb. 13, 2012

(30) Foreign Application Priority Data
Mar. 16, 2011 (JP) 2011-057807

(51) Int. Cl. B25B 11/00; H01L 21/683

(52) U.S. Cl. 269/305

(57) ABSTRACT

A substrate support jig that reduces residual droplets liable to remain on a support contact point of a thin plate substrate and the substrate support jig is disclosed. The substrate support jig used for cleaning a substrate and subsequently carrying out a Marangoni drying includes a support plate for holding the substrate upright, wherein the support plate has a groove at a contact point for supporting the substrate, and a contact angle of a surface of the support plate in case of pure water is 15 degrees or less.

### CROSS REFERENCE TO RELATED APPLICATION

The entire disclosure of the inventor's corresponding Japanese patent application, Serial No. JP PA 2011-057807, filed Mar. 16, 2011, is incorporated herein by reference.

### BACKGROUND OF THE INVENTION

1. Technical Field

The present invention relates to a substrate support jig for drying a wet substrate, wherein subject substrates include a magnetic recording medium substrate, a photomask substrate, a semiconductor substrate, a display substrate, and the like.

2. Related Art

In recent years, there has been a dramatic increase in the accuracy of semiconductors, display and magnetic recording media, and the like, and, for example, a further increase in recording density and low noise are required of a magnetic recording medium used in a magnetic recording device (HDD), which is one information recording device supporting an advanced information society. In order to meet this requirement, extremely high cleanliness is required in the manufacturing process of the magnetic recording medium. For example, it is also useful to reduce stains and the like occurring when drying after cleaning a medium substrate with a solvent. The invention, relating to a reduction of stains and the like occurring when drying the solvent, will be described with a magnetic recording medium substrate as an example.

Heretofore, various drying methods have been proposed as a drying method for the reduction of those kinds of stain occurring when drying after cleaning a substrate with a solvent. For example, a drying (IPA vapor drying) using an isopropyl alcohol (IPA) vapor, drying by pulling up from pure warm water, spin drying by rotating the substrate at high speed, and the like, have been used.

However, there are problems with the IPA vapor drying method, such as a deterioration in quality due to moisture contained in the IPA and the use of a large amount of IPA, there are also drying stains with the spin drying, and with the drying method of pulling up from pure warm water, there is a problem of defects caused by residual droplets (water marks), and the like. For these reasons, a drying method that utilizes a Marangoni convection has been used in recent years. However, in keeping with the increase in required quality, residual droplets have become an important problem with the Marangoni drying method too. The cause is recognized as being that droplets remain on a contact portion between a substrate and a support plate thereof. For this reason, with the Marangoni drying method, there are known a structure wherein a contact point portion between a substrate and a drying jig is of a pointed form, and there is a slit in the V-shaped contact point portion (JP-A-6-150313), a structure including a mechanism that suctions and removes droplets (JP-A-11-297808), and a drying method or drying jig that reduces droplets remaining in a contact portion by drying a substrate using a drying jig that includes a surface groove portion of a support member for supporting the substrate by point contact and a slit in a lower portion of the surface groove for removing water held in the point contact portion, and includes a support member as a surface material whose angle of contact with water is 60° or more (JP-A-10-162355).

However, owing to a further increase in required quality, the level at which the amount of residual droplets is seen as a problem is becoming ever stricter, and the situation is such that improvement using the heretofore known measures is difficult. This is because even with the improvements described in JP-A-6-150313, JP-A-11-297808, and JP-A-10-162355, although there is a decrease in droplets forming between the substrate and support plate, the droplets are not eliminated. Even with the method whereby the droplets are suctioned, the droplets are suctioned in a condition in which the substrate is raised by pulling it out of the liquid, meaning that the substrate is left in a condition in which droplets are formed. Also, even when there is a slit in the lower portion of the groove supporting the substrate, a liquid such as water remains in the slit portion without being discharged, meaning that the effect of reducing the amount of residual droplets is also limited.

### SUMMARY OF THE INVENTION

The invention having been contrived bearing in mind the heretofore described problems, an object of the invention is to provide a substrate support jig that reduces residual droplets liable to remain on a support contact point of a substrate and the substrate support jig, and enables good quality, stable drying, when drying with a drying method using a Marangoni convection.

In order to achieve the object of the invention, one aspect of the invention is a substrate support jig used for cleaning a substrate and subsequently carrying out a Marangoni drying, including a support plate for holding the substrate upright, wherein the support plate has a groove at a contact point for supporting the substrate, and a contact angle of a surface of the support plate in case of pure water is 15 degrees or less.

Also, a substrate support jig used for cleaning a plurality of substrates, and subsequently carrying out a Marangoni drying, includes a support plate for holding the substrates upright in parallel at predetermined intervals, wherein the support plate has notched grooves at the predetermined intervals in an upper edge thereof as contact points for supporting the substrates, and the contact angle of a surface of the support plate in case of pure water is 15 degrees or less. It is preferable that the substrate support jig includes support plates disposed in three or more rows in a direction perpendicular to a main surface of the substrate in order to hold the plurality of substrates at three or more support points. Also, it is also preferable that a cut out slit having an opening portion of a width less than the thickness of the substrate is provided in a bottom portion of the groove.

It is desirable that a metal oxide film is formed on a surface of the support plate.

It is desirable that an irregularity is formed on the surface of the support plate.

Furthermore, the substrate can be any of a magnetic recording medium substrate, a semiconductor processing photomask substrate, a semiconductor substrate, or a display substrate.

According to the invention, it is possible to provide a substrate support jig that reduces residual droplets liable to remain on a support contact point of a substrate and the substrate support jig, and enables good quality, stable drying, when drying with a drying method using a Marangoni convection.

### BRIEF DESCRIPTION OF THE DRAWINGS

FIGS. 1A and 1B are outline sectional views that illustrate the principle of a drying method utilizing a Marangoni convection, and show a surface tension condition in the vicinity of an interface between a substrate and a solvent;

FIGS. 2A to 2C are a frontal view and partial enlargements of side views of a substrate support jig showing a condition in which a substrate is set in a substrate support jig of the invention;

FIG. 3 is a drawing of the relationship between a contact angle of a surface of a support plate of the substrate support jig in case of pure water and the incidence (%) of residual droplets; and

FIG. 4 is a perspective view showing an embodiment of the substrate support jig of the invention.

### DETAILED DESCRIPTION OF THE EMBODIMENTS

Hereafter, a detailed description will be given, referring to the drawings, of an embodiment according to a substrate support jig of the invention. Provided that it does not depart from the scope thereof, the invention is not limited to the details of the embodiment described hereafter.

Firstly, a description will be given of a Marangoni drying method. The Marangoni drying is a drying method whereby a cleaning subject is cleaned and dried, utilizing a Marangoni convection generated between solutions with differing surface tensions, by pulling the cleaning subject up from a liquid with a high surface tension at a slow speed of, for example, 1 mm/second or less, through the vapor of a liquid with a low surface tension, and removing foreign material on the surface of the cleaning subject by washing them off along with the liquid.

In the invention, hereafter, a description will be given using a disc-like or donut-like magnetic recording medium substrate as a substrate. However, regardless of whether the form of the substrate is disc-like, donut-like, elliptical, quadrilateral (square or rectangular), or the like, a place supported may also be on either an outer edge or inner diameter edge.

In the following description, the magnetic recording medium substrate will be abbreviated to simply “the substrate”.

It is desirable that a contact angle (in case of pure water) between the substrate and the surface of a support plate in direct contact with the substrate, supporting and holding the substrate, is small. In particular, it is found that, by the support plate surface being in a superhydrophilic (a contact angle θ is less than 15 degrees) condition, it is possible to reduce residual droplets remaining on the substrate when pulling the substrate up from the liquid further than with a heretofore known drying method, virtually eliminating them.

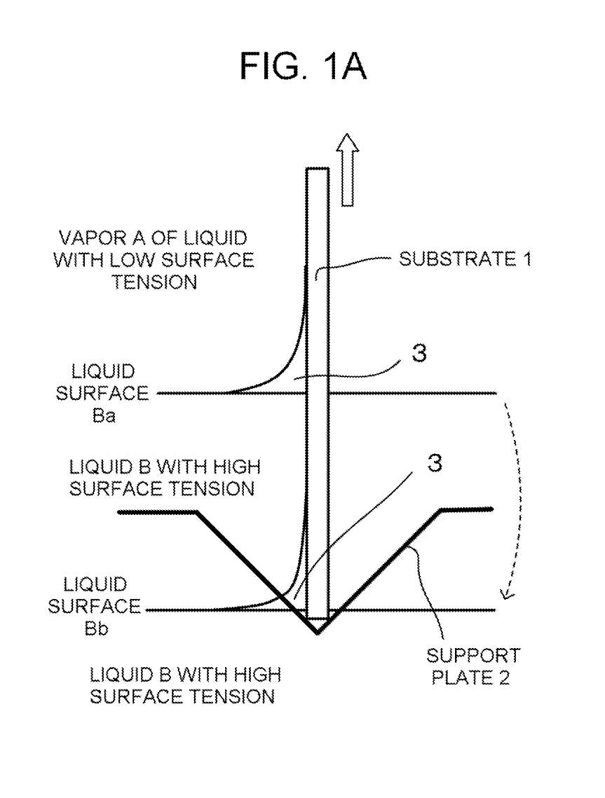

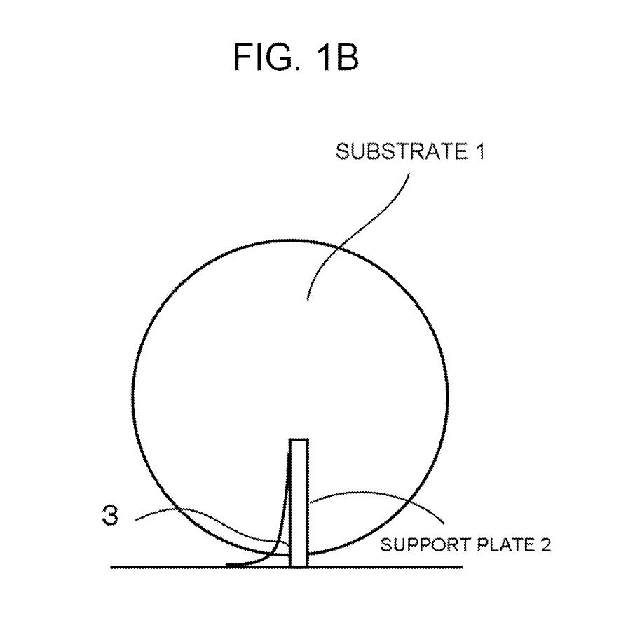

FIGS. 1A and 1B, being drawings illustrating the principle of the Marangoni drying, are outline sectional views showing a substrate and a liquid (solvent), and a surface tension condition in the vicinity of their interface. FIG. 1A, being an outline sectional view showing a method of pulling the substrate up from a cleaning liquid solvent in a condition in which the substrate is held on a support plate of a substrate support jig, is an outline sectional view including the cleaning liquid solvent seen from a side surface (a direction parallel to a substrate main surface) of the substrate being pulled up.

FIG. 1B is a frontal view (a view seen from a direction perpendicular to the main surface of the substrate) seen from in front of the substrate. In FIG. 1A, when a drying subject (the substrate 1) is pulled up from a liquid B, which is a solvent with a high surface tension, into an environment filled with a vapor A of a solvent with a low surface tension, regions 3, which are a region with a high concentration of the vapor A of the solvent with a low surface tension and a region with a high concentration of the liquid B, which is the solvent with a high surface tension, are formed on the surface of the substrate 1. In FIG. 1A, the direction in which the substrate 1 is pulled up is shown by a white arrow. Also, in FIG. 1A, in order to show a way of the substrate being pulled up, the way of the substrate being pulled up is shown relatively by lowering the liquid surface, rather than by moving the substrate 1. Consequently, the liquid surface before the substrate 1 is pulled up is a liquid surface Ba, while the liquid surface after the substrate 1 is pulled up is a liquid surface Bb. At this time, convection is generated in the regions 3 being pulled up along the surface of the substrate 1 by the surface tension on the surface of the substrate 1, from the region with a high concentration of the vapor A of the solvent with a low surface tension in an upper portion toward the region with a high concentration of the liquid B, which is the solvent with a high surface tension, in a lower portion. This convection is called Marangoni convection. As a result of the convection, foreign material, and the like, on the surface of the substrate 1 are washed off along with the liquid. However, in the event that wettability of the substrate 1 surface is poor at this time, generation of the Marangoni convection is insufficient, the effect is lost, and the number of foreign material remaining increases. The same also applying to a surface of a support plate 2 of the substrate support jig in which the substrate 1 is housed, when surface tension on the surface of the support plate 2 is high, and wettability is good, the Marangoni convection works smoothly, as shown in FIG. 1B, and the liquid flows smoothly downward, and is removed. However, when the wettability of the support plate 2 surface is poor, that is, when the surface tension is low, the surface tension of the liquid B, which is the solvent with a high surface tension, in the region with a high concentration of the liquid B, which is the solvent with a high surface tension, becomes relatively high. As a result of this, the liquid B, which is the solvent with a high surface tension, attempts to reduce its surface area on the surface of the support plate 2, taking on a droplet form. As a result of this, the convection does not work smoothly, meaning that residual droplets are likely to occur.

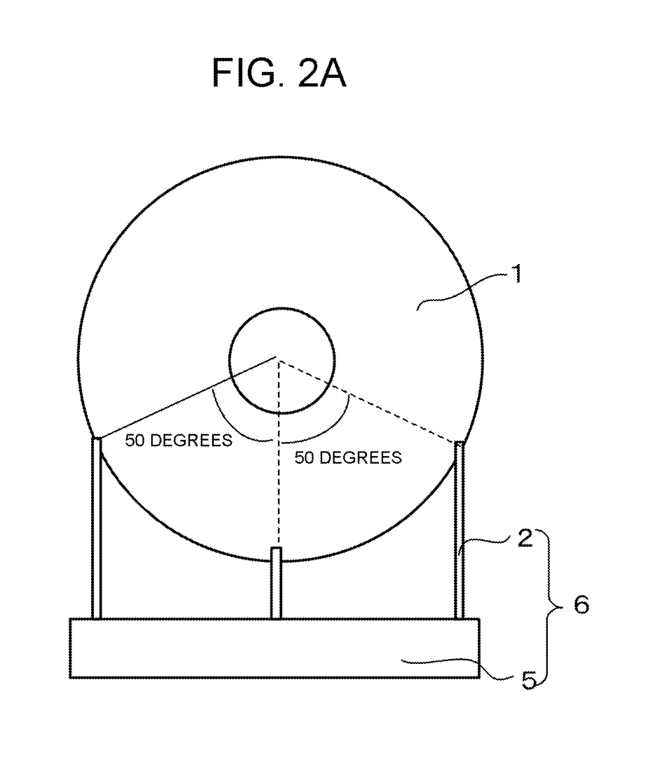

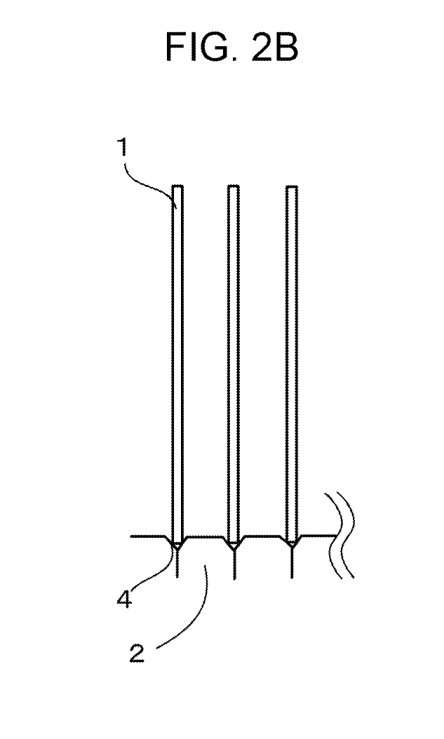

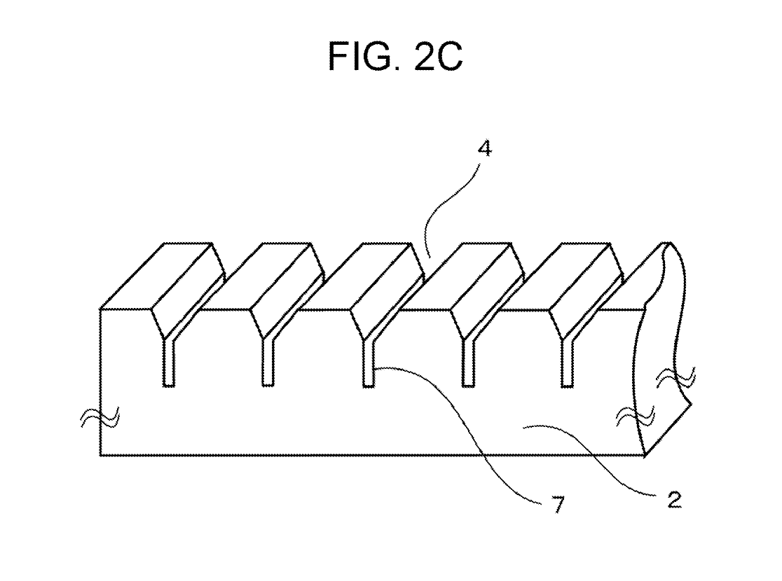

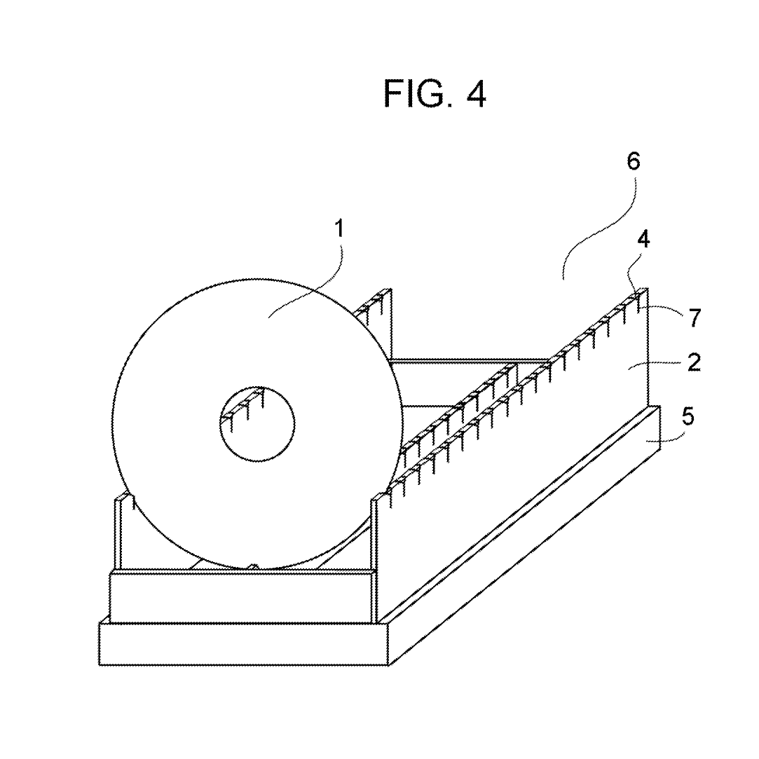

FIGS. 2A to 2C show details of a substrate support jig 6, which includes a support plate 2, in an upper edge of which a V-shaped groove 4 is provided, and a support stand 5 that fixes the support plate, as a contact that supports the substrate 1. FIG. 2A is a side view showing a figure in which the substrate 1 is housed in the substrate support jig 6. FIG. 2B is an enlarged frontal view of a contact portion showing a figure in which the substrate 1 is held in the groove 4 provided in the upper edge of the support plate 2. FIG. 2C is an enlarged perspective view showing the V-shaped groove 4 provided in the upper edge of the support plate 2 and a slit 7 portion provided in a bottom portion of the groove 4. FIG. 4 is a perspective view of the substrate support jig 6. Although the support plate 2 is not limited to the forms, in particular the forms of the groove 4 and slit 7, shown in FIG. 2, it is desirable to maintain an ability to hold a large number of the substrates 1 in terms of mass productivity, and that the contact area is as small as possible in terms of drying quality. Although the V-form angle of inclination is optional, an angle compatible with the chamfer angle of the substrate 1 outer peripheral edge surface is preferable in terms of holding ability.

Also, although a substrate support jig 6 that supports at three points is shown in FIG. 2A, this substrate support jig 6 is not limiting. Also, it is preferable that the form of the slit 7 provided in the bottom portion of the V-shaped groove 4 includes an opening portion whose width is at least less than the thickness of the substrate 1, in order that the substrate 1 does not fall into the slit 7. Provided that the width of the opening portion of the slit 7 is less than the thickness of the substrate 1 in this way, the width below the opening portion may be greater. It is possible to make the slit 7 of a form such that a removal into the slit 7 of droplets liable to remain at a contact point between the substrate 1 and groove 4, or a further removal from the slit 7 to below the substrate plate 2, is easy.

However, it is also possible to provide only the groove 4 with no slit 7 provided. As the substrate support jig 6 of the invention is one that supports and holds the substrate 1 with the support plate 2, the substrate holder may be other than that shown in FIG. 4, which supports at three points, provided that it is possible to reliably hold the substrate 1, although it is preferable that support is at three points or more. Although a configuration including three substrate plates 2 in a direction perpendicular to the surface of the substrate 1 is shown in FIGS. 2A to 2C and FIG. 4, the substrate plates 2 may also be integrated. Also, a configuration may be such that a plurality of support plates 2 are disposed parallel to the surface of the substrate 1. In this case, it is sufficient that a plurality of grooves 4 are formed in one support plate 2 in order that one support plate 2 supports one substrate 1 at a plurality of contact points. Also, although a substrate support jig that holds a plurality of substrates 1 is shown in FIGS. 2A to 2C and FIG. 4, the substrate support jig may also be one that supports only one substrate 1. Also, it is also possible to add to the substrate support jig of FIG. 4, as appropriate, a frame, a handle, and the like, convenient for the substrate support jig to be put into and taken out of a cleaning tank, and carried around.

A metal oxide film with good wettability, durability, corrosion resistance, and the like, is desirable as a material of the surface of the support plate 2 configuring the substrate support jig 6 of the invention. As an oxide film has a property of attracting a hydroxyl to a clean surface, hydrophilia, that is, water wettability, improves, and it is possible to reduce a contact angle in case of pure water. Specifically, oxide films of aluminum oxide, titanium oxide, strontium titanate, zinc oxide, tin oxide, silicon oxide, or the like, are proposed, but these are not limiting. For example, in a case in which the surface of the support plate 2 is of aluminum oxide, it is possible to form the support plate 2 by anodizing aluminum or an aluminum alloy, forming an anode oxide film. Alternatively, it is possible that the support plate 2 is such that an aluminum oxide film is deposited on the surface only by a PVD, CVD, or the like, using a sputtering or the like on a metal such as iron, or a ceramic, or that the support plate 2 is such that an aluminum oxide film, or the like, formed by sintering is deposited. In terms of strength, an aluminum alloy is desirable as the base material of the support plate 2 used in the anode oxide film, and in particular, an aluminum alloy of a 3000, 4000, 5000, 6000, or 7000 series is preferable.

Also, a metal oxide film of titanium oxide, strontium titanate, zinc oxide, tin oxide, silicon oxide, or the like, is effective as it exhibits superhydrophilia by being irradiated with ultraviolet light. Although the durability of hydrophilia varies depending on the environment, lasting for between a few hours and several dozen hours, it recovers when a regular irradiation with ultraviolet light is carried out. Although a low pressure mercury vapor lamp (dominant wavelengths 185 nm and 254 nm) and various kinds of excimer lamp (for example, Kr gas: 146 nm) exist as ultraviolet light irradiation devices, any lamp can be used provided that it has a wavelength with a band gap energy greater than the band gap energy of the material to be coated. This is because the surface binding of an irradiated film is chemically stimulated by irradiation with a lamp with this kind of high energy wavelength, and modified to a hydrophilic surface. In an actual manufacturing process, the substrate support jig 6 including the support plate 2 is separated from the substrate 1 after the previously described drying process, and returned again from an unload side to a load side processing line, meaning that is sufficient that the substrate support jig 6 is irradiated before being returned to the processing line. Specifically, it is preferable that the processing line is such that an ultraviolet light irradiation lamp is provided in the upper portion of the cleaning tank in which the cleaning and drying process is implemented using the substrate support jig in which the substrate is housed. Also, as previously described, anodization, a sol-gel method, a sputtering method, a laser deposition method, and the like, exist for the formation of the metal oxide film, but these are not limiting.

Other than the previously described aluminum based metal, glass, a ceramic, or the like, are also possible as the base material of the support plate 2. When using a glass material formed from silicon dioxide or a glass material based on silicon oxide as the base material of the support plate, the materials themselves exhibit hydrophilia, meaning that they may be used as they are, without specially providing any hydrophilic film on the surface. However, even with the previously described support plate exhibiting hydrophilia, it often happens that, when the support plate is exposed to the atmosphere, wettability deteriorates, and the contact angle increases, due to foreign material including hydrocarbons being adsorbed to the surface. Because of this, it is preferable, before using, to remove the foreign material including hydrocarbons by immersion or exposure using an acid, alkaline, or ozone oxidation.

Also, it is also possible to provide the surface of the base material of the support plate with a slight irregularity in order to further increase hydrophilia and reduce the contact angle. For example, in the case of a silicon oxide or a glass material based on silicon oxide, this is done by inserting the glass in hydrofluoric acid (30° C.) with a concentration of around 3 to 4% by weight, and leaving it for around 30 to 40 minutes. Also, a process of providing a slight irregularity, whereby a plasma processing with argon, hydrogen, nitrogen, or the like, is performed on the surface, may be carried out.

A Marangoni drying method, whereby a clean substrate 1 cleaned with a detergent, or the like, and rinsed with pure water, or the like, is immersed in pure water, the environment on a gas phase side is filled with a vapor including a solvent with a low surface tension, such as IPA, and the substrate 1 is dried by being slowly pulled up, is performed as a drying method. Pure water is mainly used as the solvent with a high surface tension, and IPA (isopropyl alcohol) as the solvent with a low surface tension. However, these not being limiting, it is sufficient that there is a large gap between the surface tensions of the two solvents. Also, as the solvent with a low surface tension is gasified, it is desirable that it has a low boiling point (excluding a harmful substance, a solvent with a low flash point, or the like). In this case, the previously described support plate is used as the substrate support jig of the invention.

### Working Example 1

Hereafter, a description will be given of a substrate support jig for a magnetic recording medium substrate as the substrate support jig of the invention. The magnetic recording medium substrate (hereafter, the substrate 1) is of a disc form with an outer diameter of 65 mm, an inner diameter of 20 mm, and a thickness of 0.635 mm, and a clean alumino-silicate glass that has undergone a plurality of polishing processes and a plurality of cleaning processes is used as the material of the substrate 1. The surface of the substrate 1 is smooth, Ra (center line average roughness) is 0.2 nm or less, the external edge surface is chamfered to 45 degrees, and the surface is polished to be a mirror surface.

The substrate support jig of the invention is shown in FIGS. 2A to 2C and FIG. 4. The form of the support plate 2 indirect contact with, and supporting, the substrate 1 is such that the width (thickness) is 0.4 mm, the depth of the V-shaped groove 4 is 1.5 mm, and the angle between the two interior inclined surfaces opened in a V-shape is 90°, wherein the slit 7 with a length of 3 mm and a width of 0.3 mm is provided in the V-shaped valley portion (bottom portion). The V-shaped groove 4 is provided in 25 places in order that it is possible to house, clean, and dry 25 substrates at one time. In FIG. 4, for ease of drawing, the groove 4 is depicted in only 18 places, but it is assumed that the groove 4 is provided in 25 places.

The support plate 2 is disposed in parallel in three rows in a direction perpendicular to the main surface of the substrate 1 in order that it can reliably hold the substrate 1 upright with a three-point support. The three rows are disposed in such a way as to support by coming into contact in three places, one place in the lowermost portion of the center of the upright substrate 1, and two places where lines extending at 50 degrees to the left and right on the substrate surface in case of a vertical line from the substrate center intersect with the periphery of the substrate 1.

### Experiment Example 1

A support plate wherein an anode oxide film is formed on the surface of an aluminum alloy is fabricated as a support plate for Experiment Example 1 according to the invention. That is, an aluminum-magnesium alloy (5086 series) is formed on the form of the support plate 2 illustrated in FIGS. 2A to 2C. Subsequently, a degreasing process and etching process are carried out using a 10% aqueous sodium hydroxide. Subsequently, the support plate 2 is anodized for one hour in an anodizing electrolytic (phosphoric acid concentration 2N) solution of 20° C. at a current density of 100 A/m², obtaining a film with a thickness of 8 μm. When the contact angle in case of pure water is checked without performing a sealing process, it is found to be 15 degrees.

### Experiment Example 2

A support plate wherein a titanium dioxide film is formed on the surface of a titanium is fabricated as a support plate for Experiment Example 2 according to the invention. That is, there is fabricated a support plate wherein a titanium dioxide film is formed as the surface material of an titanium formed on the form of the support plate 2 illustrated in FIGS. 2A to 2C. As a formation method, the support plate is connected to an anode, an anodizing process is carried out in a 2% by weight aqueous sulfuric acid, and a titanium dioxide film with a thickness of 10 μm is formed. Furthermore, after cleaning and drying, a heating process is carried out for approximately two hours at 400° C.

Next, when an ultraviolet light irradiation process is carried out on the support plate fabricated for Experiment Example 2 with a low pressure mercury vapor lamp (dominant wavelengths 185 nm and 254 nm) under atmospheric conditions, the contact angle of the titanium dioxide film surface of the support plate surface in case of pure water attained a value of 5 degrees or less.

### Comparison Examples 1, 2, and 3

Support plates using the following materials are fabricated as Comparison Examples 1, 2, and 3, and the contact angles in case of pure water are measured.

TABLE 1

| | | Contact Angle |
|---|---|---|
| | Support Plate Material | (degrees) |
| Comparison | Experiment Example 2 with no ultraviolet | 65 |
| Example 1 | light irradiation process | |
| Comparison | SUS304 | 30 |
| Example 2 | | |
| Comparison | Quartz glass | 20 |
| Example 3 | | |

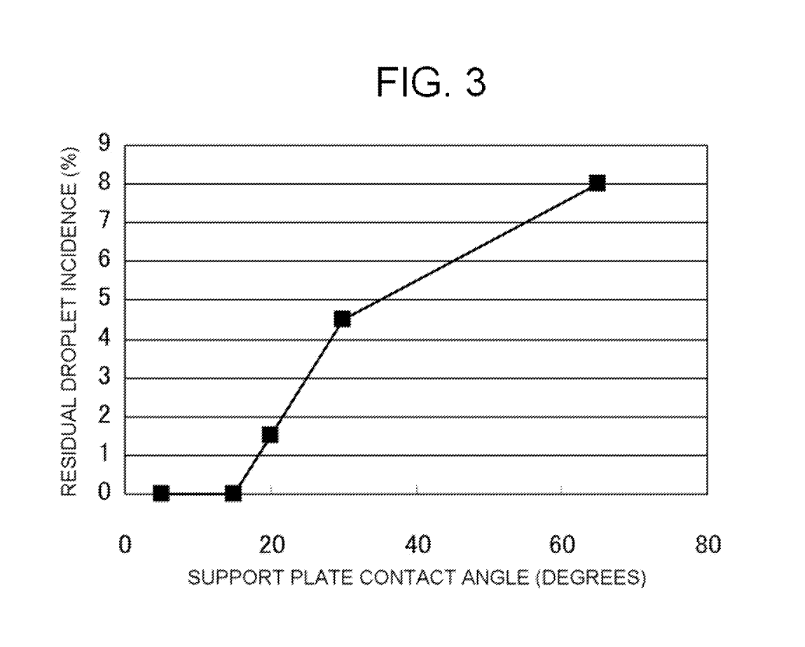

Some glass substrates are housed as a cleaning subject substrate in substrate support jigs using the support plates fabricated in Experiment Examples 1 and 2 and Comparison Examples 1, 2, and 3. Using pure water as a solvent with a high surface tension, drying is carried out using a Marangoni drying whereby the whole of the substrate support jig in which these glass substrates are housed is pulled up from a condition in which it is immersed in ultrapure water through a vapor of IPA, which is a solvent with a low surface tension, at 0.4 mm/second, and the incidence of residual droplets on the glass substrate is evaluated. A visual check and an optical surface analyzer (a KLA-Tencor manufactured OSA6100) are used in the evaluation, and one batch of 25 glass substrates is examined for the support plate of each of the Experiment Examples and Comparison Examples. The examination results are shown in FIG. 3, which is a drawing showing the relationship between the contact angle of the support plate surface and the incidence of residual droplets. FIG. 3 shows that, as the contact angles of the support plate surfaces in the substrate support jigs having the support plates of Experiment Examples 1 and 2 according to the invention are 15 degrees and 5 degrees respectively, there is no occurrence of residual droplets on the glass substrate. Furthermore, it is seen that, as the contact angles of the support plate surfaces in Comparison Examples 1, 2, and 3 are 65 degrees, 30 degrees, and 20 degrees respectively, the incidences of residual droplets are 8%, 4.5%, and 1.5%. From these results, it can be said to be clear that the substrate support jigs using the support plates according to Experiment Examples 1 and 2 of the invention exhibit a superior effect in reducing residual droplets on the glass substrate.

This kind of support plate surface with a contact angle of 15 degrees or less is obtained by forming a metal oxide with the durability, and the like, required of a substrate support jig on the surface of the support plate. An aluminum anode oxide film is particularly desirable, as the contact angle in case of pure water is 15 degrees or less, and furthermore, it also has superior durability. Also, forming a film with titanium oxide, strontium titanate, zinc oxide, tin oxide, silicon oxide, or the like, which are other metal oxides, is effective, as it is possible to obtain a contact angle of 10 degrees or less using the photocatalytic function of an ultraviolet light irradiation.

Herein, the form of the support plate used in the substrate support jig of the invention indicates a support plate that has groove forms of a V shape, U shape, or shape similar thereto, in the upper edge, and that can receive, support, and hold a substrate with the inclined surfaces of the grooves as contact points, as shown in FIGS. 1A and 1B and 2A to 2C. It is desirable that the substrate is held in the substrate support jig in such a way that the substrate surface is perpendicular to the liquid surface. Also, the substrate support jig of the invention being of a form that takes into consideration holding ability and ease of drying depending on the form and weight of a subject substrate, a sectional form thereof is not limited to being quadrilateral, but may be circular, elliptical, quadrilateral, or a form that is a combination thereof. With the groove form too, although an inner surface angle of 90° is desirable, this is not limiting, and also, although it is preferable that there is a slit in the bottom portion of the groove, the slit can also be eliminated. Furthermore, heretofore, with the substrate support jig described with reference to FIGS. 2A to 2C and 4, the structure is such as to support a plurality of magnetic recording medium substrates upright in parallel at predetermined intervals, but the structure may be such as to support one magnetic recording medium substrate.

It will be apparent to those skilled in the art that various modifications and variations can be made to the method and apparatus of the present disclosure. Other embodiments of the method and apparatus will be apparent to those skilled in the art from consideration of the specification and practice of the method and system disclosed herein. It is intended that the specification and examples be considered as exemplary only, with a true scope of the disclosure being indicated by the following claims and their equivalents.

What is claimed is:

1. A substrate support jig configured to clean a plurality of substrates using a batch method, and configured to subsequently carry out a Marangoni drying, comprising:
a support plate configured to hold the plurality of the substrates upright in parallel at predetermined intervals, wherein
the support plate includes grooves at the predetermined intervals as contact points configured to support the plurality of substrates.

2. The substrate support jig according to claim 1, wherein the substrate support jig includes support plates disposed in three or more rows in a direction perpendicular to a main surface of the substrate and configured to hold the substrate at three or more support points.

3. The substrate support jig according to claim 1, wherein a metal oxide film is formed on a surface of the support plate.

4. The substrate support jig according to claim 3, wherein the metal oxide film is an aluminum anode oxide film.

5. A substrate support jig configured to clean a substrate and to subsequently carry out a Marangoni drying, comprising:
a support plate configured to hold the substrate upright, wherein
the support plate includes a groove at a contact point configured to support the substrate, and
a contact angle of a surface of the support plate in the case of pure water is 15 degrees or less.

6. The substrate support jig according to claim 5, wherein the substrate support jig includes support plates disposed in three or more rows in a direction perpendicular to a main surface of the substrate and configured to hold the substrate at three or more support points.

7. The substrate support jig according to claim 5, wherein a cut-out slit having an opening portion of a width less than the thickness of the substrate is provided in a bottom portion of the groove.

8. The substrate support jig according to claim 5, wherein a metal oxide film is formed on a surface of the support plate.

9. The substrate support jig according to claim 8, wherein the metal oxide film includes aluminum anode oxide.

10. The substrate support jig according to claim 8, wherein the metal oxide film includes at least one of titanium oxide, strontium titanate, zinc oxide, tin oxide, or silicon oxide.

11. The substrate support jig according to claim 5, wherein an irregularity is formed on the surface of the support plate.

12. The substrate support jig according to claim 5, wherein the substrate is one of a magnetic recording medium substrate, a semiconductor processing photomask substrate, a semiconductor substrate, or a display substrate.
